(19) United States
(12) Patent Application Publication
(10) Pub. No.: US 2019/0320524 A1
(43) Pub. Date: Oct. 17, 2019

(54) PCBA WITH POINT FIELD DETECTOR AND MAGNETIC SHIELDING ARRAY LOCATED ON SAME SIDE OF A CONDUCTOR

(71) Applicant: GM Global Technology Operations LLC, Detroit, MI (US)

(72) Inventors: He Niu, Rochester, MI (US); Sainan Xue, Torrance, CA (US); Marko Jaksic, Shelby Township, MI (US); Zilai Zhao, Novi, MI (US)

(73) Assignee: GM Global Technology Operations LLC, Detroit, MI (US)

(21) Appl. No.: 15/952,893

(22) Filed: Apr. 13, 2018

(51) Int. Cl. H05K 1/02; H05K 9/00; H05K 1/18; G01R 15/20; G01R 19/00; H01M 10/42; H01M 10/48

(52) U.S. Cl. CPC H05K 1/0216; H05K 9/0022; H05K 1/181; G01R 15/202; G01R 19/0092; G01R 31/3644; H01M 10/4207; H01M 10/482; H05K 2201/10272; H05K 2201/10151; H05K 2201/10371; H01M 10/425

(57) ABSTRACT

An electrical device includes an electrical conductor and a printed circuit board assembly (PCBA). The PCBA includes a planar substrate having first and second primary surfaces. The second primary surface is adjacent to the electrical conductor. A point field detector is mounted to the first primary surface. A magnetic shielding array is constructed of a magnetic material, e.g., having a relative magnetic permeability of about 100-1000. The magnetic shielding array is mounted to or situated on the first and/or second primary surface of the planar substrate, and includes first and second flux shield portions flanking the point field detector. The point field detector and the magnetic shielding array are both located on the same side of the electrical conductor with respect to each other.

### INTRODUCTION

An electrical current in an electric machine drive or an electrochemical battery cell stack may be monitored and regulated by a drive controller or a battery controller using feedback signals from board-mounted sensor components. Such sensor components are typically arranged on a current sense board. The current sense board may be in communication with a gate drive board of a power converter, with measured current levels used by the drive controller or battery controller to control power flow to and from the electric machine or the battery stack.

To this end, a current sense board may include a sensor setup in which individual senselines are electrically connected to surface-mounted Hall-effect sensors or other point field detectors. The point field detectors measure and report current flow to the drive controller or the battery controller as part of an overall electric machine drive or battery control strategy. Performance of the current sense board and/or the gate drive board may be disrupted by electromagnetic interference-induced crosstalk between neighboring board-mounted components and conductive paths.

### SUMMARY

An electrical device is disclosed herein that, according to an exemplary embodiment, includes an electrical conductor and a printed circuit board assembly (PCBA). The PCBA includes a planar substrate having first and second primary surfaces, e.g., an upper and lower surface in a typical orientation, with the second primary surface being adjacent to the electrical conductor. A point field detector is mounted to the first or second primary surface of the substrate. A magnetic shielding array is arranged or situated on the first and/or second primary surface(s), with the magnetic shielding array having first and second flux shield portions that together flank the point field detector.

In other words, the point field detector and the magnetic shielding array are located on a common side of the conductor, i.e., the same side of the conductor with respect to each other. Such a configuration may be contrasted with approaches employing a U-shaped or C-shaped unitary flux shield on an underside of the PCBA, i.e., with the conductor disposed between the substrate and the unitary flux shield opposite to a side of the substrate to which the point field detector is mounted. The present approach is intended to help improve assembly and packaging efficiency while reducing weight of the PCBA, with such benefits provided without contributing to additional signal noise or cross-talk between other surface-mounted components of the PCBA.

The above summary is not intended to represent every embodiment or aspect of the present disclosure. Rather, the foregoing summary exemplifies certain novel aspects and features as set forth herein. The above noted and other features and advantages of the present disclosure will be readily apparent from the following detailed description of representative embodiments and modes for carrying out the present disclosure when taken in connection with the accompanying drawings and the appended claims.

### BRIEF DESCRIPTION OF THE DRAWINGS

FIG. 1 is a schematic perspective view illustration of an example electrical device having a conductor and a printed circuit board assembly (PCBA), with the PCBA having a point field detector flanked by a magnetic shielding array constructed as set forth herein.

FIG. 2 is a schematic side view illustration of a flux shield portion usable as part of the magnetic shielding array shown in FIG. 1.

FIG. 3 is a schematic cross-sectional illustration of the electrical device of FIG. 1 taken through cutline AA of FIG. 2.

FIGS. 4 and 5 are schematic perspective view illustrations of a current sensing portion of the electrical device shown in FIGS. 1 and 2 depicting a respective first/upper surface and second/lower surface of the PCBA.

The present disclosure is susceptible to modifications and alternative forms, with representative embodiments shown by way of example in the drawings and described in detail below. Inventive aspects of this disclosure are not limited to the particular forms disclosed. Rather, the present disclosure is intended to cover modifications, equivalents, combinations, and alternatives falling within the scope of the disclosure as defined by the appended claims.

### DETAILED DESCRIPTION

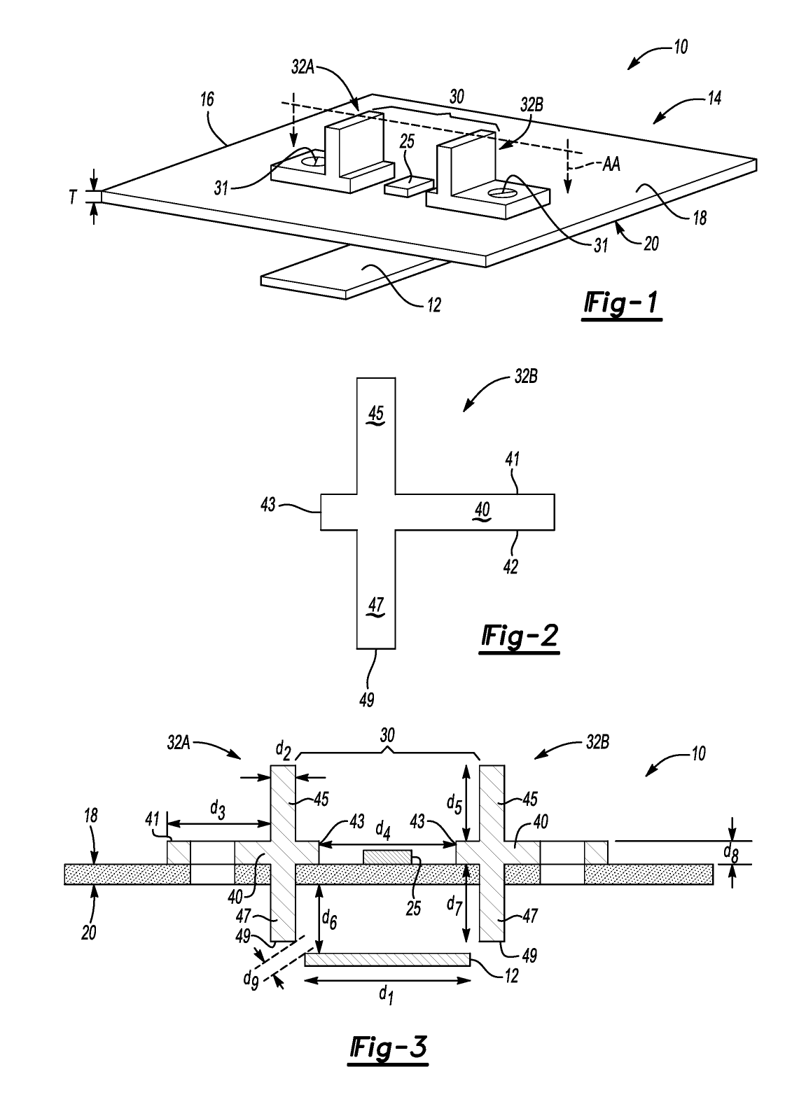

Referring to the drawings, wherein like reference numerals are used to identify like or identical components in the various views, FIG. 1 schematically illustrates an example electrical device 10. The electrical device 10, which may be configured as an integrated current sense board and gate drive board, i.e., a single board performing both functions, e.g., for a high-current battery pack (not shown) in a possible embodiment, includes an electrical conductor 12 and a printed circuit board assembly (PCBA) 14, a portion of which is depicted in FIG. 1 for illustrative simplicity. That is, the PCBA 14 as depicted may be a section or portion of a larger PCBA having various surface-mounted components, including but not limited to a point field detector 25, capacitors, resistors, inductors, and electrical connectors.

The PCBA 14 includes a planar substrate 16 constructed of a reinforced epoxy resin material or other application-specific material. The substrate 16 includes respective first and second primary surfaces 18 and 20. The first primary surface 18, in the orientation of FIG. 1, forms an upper surface of the PCBA 14. The second surface 20 thus forms a lower surface, with a thickness (T) of the substrate 16 defined by the intervening materials located between the first and second primary surfaces 18 and 20. Regardless of nominal upper/lower orientation of the substrate 16, the second primary surface 20 is located adjacent to the conductor 12. The conductor 12 may be an elongated high-current voltage bus bar as shown, e.g., an elongated rectangular plate constructed of copper, without limiting the function or structure of the conductor 12 to such an embodiment.

Various electronic components may be surface-mounted to the substrate 16 at the first surface 18 to form the PCBA 14, as will be appreciated by one of ordinary skill in the art. Within the scope of the present disclosure, such electronic components may include the point field detector 25, e.g., a coreless detector in some embodiments, flanked by a magnetic shielding array 30 as described in detail below with reference to FIGS. 2 and 3. The point field detector 25 depicted in FIG. 1 may be a multi-pin integrated circuit or chip, e.g., a Hall-effect sensor or other device potentially lacking an iron core (“coreless”), a magneto-resistor, etc. Magnetic flux produced by electrical current flowing through conductive traces and other paths of the PCBA 14 is thus measured by the point field detector 25 and reported to a controller (not shown), e.g., a battery controller, in the overall control of a battery pack or other electrical system employing the electrical device 10 of FIG. 1.

The magnetic shielding array 30 is configured to reduce external electromagnetic field interference from nearby electronic components mounted, in the illustrated embodiment, to the first primary surface 18, for instance other point field detectors 25 used elsewhere on the PCBA 14. The magnetic shielding array 30 includes respective first and second flux shield portions 32A and 32B located, in the illustrated exemplary embodiment, primarily on the first primary surface 18. That is, the majority of a total surface area and mass of the first and second flux shield portions 32A and 32B is mounted on or adjacent to the first primary surface 18. However, a portion of the first and second flux shield portions 32A and 32B extends through the substrate 16 as shown in FIGS. 3 and 5, extending a short distance beyond the second primary surface 20 in order to perform the flux shielding functions detailed below with reference to FIG. 3. In other embodiments, the majority of the magnetic shielding array may be situated on the second primary surface 20, along with the point field detector 25, within the scope of the disclosure, provided the point field detector 25 and the first and second flux shield portions 32A and 32B are located on the same side of the electrical conductor 12.

The first and second flux shield portions 32A and 32B, which may be identically configured as shown in some embodiments or of different geometries, are connected to the first primary surface 18. For example, the first and second flux shield portions 32A and 32B may be directly mounted to the substrate 16 via fasteners 31, i.e., through holes 44 in the first and second flux shield portions 32A and 32B as shown in FIG. 3. Such a configuration has the benefit of eliminating the need for soldering, plastic molding, or adhesives. However, such techniques may be used in the alternative. The point field detector 25 is disposed between the respective first and second flux shield portions 32A and 32B, i.e., the first and second flux shield portions 32A and 32B flank the point field detector 25 in the installed position shown in FIG. 1.

Referring now to FIG. 2, the second flux shield portion 32B is shown schematically. As noted above, the first flux shield portion 32A may be identically configured, with an installed position oriented 180° opposite to the orientation shown in FIG. 2. Therefore, the following description of the second flux shield portion 32B applies equally to the first flux shield portion 32A.

The second flux shield portion 32B includes a planar base member 40 with respective first and second primary surfaces 41 and 42. The base member 40 is also intersected by radial wall members 45 and 47. In the exemplary embodiment depicted in FIG. 2, the radial wall members 45 and 47 extend orthogonally outward from the first primary surface 41 of the base member 40 to form a generally T-shaped configuration. A secondary surface 49 of radial wall member 47 in the installed position (see FIG. 3) is thus disposed immediately adjacent to the conductor 12.

When the second flux shield portion 32B is affixed to the first primary surface 18 of the substrate 16 shown in FIG. 1, the second primary surface 42 of the base member 40, i.e., an underside or lower surface in a typical orientation, is located immediately adjacent to the first primary surface 18 of the substrate 16. In the installed state of FIG. 3, therefore, a respective end surface 43 of the base member 40 of each of the first and second flux shield portions 32A and 32B is located adjacent to the point field detector 25. In this manner, the point field detector 25 is flanked by the end surfaces 43. i.e., with no intervening structure being present between the point field detector 25 and the end surfaces 43.

The first and second flux shield portions 32A and 32B may be constructed of an application-suitable material having a low magnetic resistance. Such materials, within the scope of the present disclosure, include ferromagnetic materials or other materials having a relative magnetic permeability (μᵣ) greater than 50, and generally in the range of about 100 to about 1000, with “about” meaning within ±10 percent. As will be appreciated, the term “magnetic permeability” as used herein is a measure of a given material's ability to support formation of a magnetic field, i.e., the degree of magnetization obtained by the material in the presence of an applied magnetic field. In some embodiments, the first and second flux shield portions 32A and 32B may be constructed of elemental nickel and/or iron, e.g., nickel iron, or of a silicon iron alloy. Other materials include ferritic stainless steel and martensitic stainless steel, without limiting the scope of the disclosure to such materials.

Referring to FIG. 3, the electrical device 10 shown in FIG. 1 is shown in a cross-sectional view taken through cutline AA of FIG. 1. The point field detector 25 is flanked by the first and second flux shield portions 32A and 32B, as noted above. While the point field detector 25 is shown at a centered position that is equidistant with respect to the end surfaces 43, i.e., in a symmetrical arrangement, in other embodiments the point field detector 25 may be positioned closer to one of the first and second flux shield portions 32A or 32B, depending on the flux paths present in the electrical device 10. Therefore, the symmetrical arrangement of the Figures is non-limiting.

Various dimensions d₁, d₂, d₃, d₄, d₅, d₆, d₇, d₈, and d₉ collectively define the size and relation positions of components used to construct the electrical device 10. An embodiment of the electrical device 10 may include the conductor 12 electrically conducting an electrical current of 500 amps, i.e., an example high-current application. For the example dimensions d₁-d₉ described below, the term “about” means ±10 percent, or within normal manufacturing tolerances.

In a possible construction usable with this high-current embodiment, dimension di may be about 12 millimeters (mm), with dimensions d₂, d₃, and d₄ being about 2 mm, 9 mm, and 12 mm, respectively. In the same embodiment, dimensions d₅, d₆, d₇, and d₈ may be about 6.5 mm, 7.5 mm, 6.5 mm, and 2 mm, respectively. Dimension d₈, effectively the height of the base member 40 of FIG. 2 and, as a result, of the end surfaces 43, exceeds a height of the point field detector 25, e.g., by 10 percent or more. Additionally, dimension d₉, which defines a size of an air gap between the conductor 12 and a closest portion of the radial member 47 (see FIG. 2) of the first and second flux shield portions 32A and 32B, may be about 1-2 mm. Thus, with an electrical current flowing through the conductor 12, directly into the page from the perspective of FIG. 3, magnetic flux paths would exist around the point field detector 25 bounded by the end surfaces 43. Likewise, flux paths would extend between the corresponding secondary surfaces 49 of the radial wall members 47, with such flux paths passing around the conductor 12. However, the arrangement of the first and second flux shield portions 32A and 32B ensures that flux is retained by the magnetic shielding array 30, such that cross-talk with neighboring components is minimized.

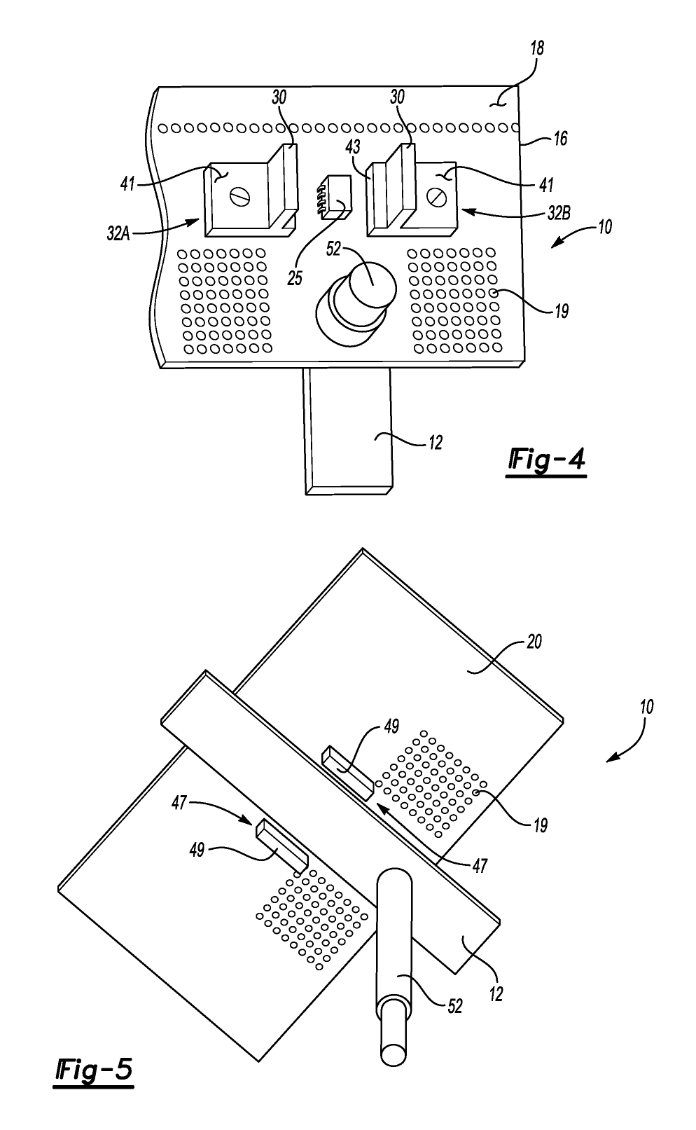

FIGS. 4 and 5 depict a portion of the electrical device 10 of FIG. 1 in an upper/top and lower/bottom perspective view, respectively, for an integrated current sense and gate drive board embodiment of the PCBA 14. In FIG. 4, weld spots 19 are depicted schematically on the first primary surface 18 adjacent to the first and second flux shield portions 32A and 32B and point field detector 25, with such weld spots 19 being representative of circuit connections in the above-noted integrated board. An elongated, non-conductive stake 52, for instance constructed of plastic, passes through the substrate 16 and, as best shown in FIG. 5, through the conductor 12. While omitted for simplicity, a plurality of similar plastic stakes 52 may be used around a perimeter of a larger PCBA 14 to align the PCBA 14 and, in particular, the point field detectors 25 with the conductors 12, and to also secure the PCBA 14 to the conductors 12.

As shown in FIG. 5, such conductors may be disposed adjacent to and, in the particular orientation of FIG. 5, below a level or plane of the PCBA 14. The radial wall member 47 protrudes from the second primary surface 20 of the PCBA 14. The distance of such protrusion corresponds to dimension d₉ of FIG. 3, and ensures that the secondary surface 49 of radial wall member 47 is disposed immediately adjacent to the conductor 12.

By using the electrical device 10 as described above, one of ordinary skill in the art will appreciate that a current sensing solution is realized in which sensing hardware, i.e., the point field detectors 25 and magnetic shielding arrays 30, are located on a single common, i.e., same, side of the conductors 12 through which a detectable electrical current is flowing. Placement of sensing setups on a single side of the conductor 12 may simplify the overall assembly process and conserve valuable packaging space relative to the construction and placement of unitary U-shaped or C-shaped magnetic shields as noted above.

While the best modes for carrying out the disclosure have been described in detail, those familiar with the art to which this disclosure relates will recognize various alternative designs and embodiments lying within the scope of the appended claims. It is intended that subject matter contained in the above description and/or shown in the accompanying drawings shall be interpreted as illustrative and not limiting.

What is claimed is:

1. An electrical device comprising:
an electrical conductor; and
a printed circuit board assembly (PCBA) having:
a planar substrate having first and second primary surfaces, wherein the second primary surface of the planar substrate is adjacent to the electrical conductor;
a point field detector mounted to the first or second primary surfaces of the planar substrate; and
a magnetic shielding array constructed of a magnetic material, wherein the magnetic shielding array is situated on at least one of the first and second primary surfaces of the planar substrate, and includes first and second flux shield portions flanking the point field detector, such that the point field detector and the magnetic shielding array are both located on a common or same side of the electrical conductor with respect to each other.

2. The electrical device of claim 1, wherein the electrical conductor is an elongated bus bar constructed of copper.

3. The electrical device of claim 1, wherein the point field detector is a Hall-effect sensor.

4. The electrical device of claim 3, wherein the Hall-effect sensor is centered between the first and second flux shield portions.

5. The electrical device of claim 4, wherein the first and second flux shield portions are separated from each other by a distance of about 12 mm.

6. The electrical device of claim 1, wherein the first and second flux shield portions include a respective planar base portion intersected by first and second radial wall members.

7. The electrical device of claim 6, wherein the second radial wall member extends through the substrate and protrudes from the second primary surface to within 1-2 mm of the conductor.

8. The electrical device of claim 6, wherein each of the respective planar base portions defines a hole, the electrical device further comprising: a pair of fasteners connecting the first and second flux shield portions to the substrate through the hole of the respective base portions.

9. The electrical device of claim 1, wherein the magnetic material has a relative magnetic permeability is in a range of about 100 to about 1000.

10. The electrical device of claim 1, wherein the PCBA is an integrated current sense board and gate drive board.

11. A printed circuit board assembly (PCBA) for use with an electrical conductor, the PCBA comprising:
a planar substrate having first and second primary surfaces;
a point field detector mounted to the first primary surface of the planar substrate; and
a magnetic shielding array constructed of a magnetic material, wherein the magnetic shielding array is connected to at least one of the first and second primary surfaces of the planar substrate, and includes first and second flux shield portions flanking the point field sensor;
wherein the PCBA is configured such that, when used within the electrical system, the point field detector and the magnetic shielding array are both located on a common or same side of the electrical conductor, and the second primary surface of the planar substrate is adjacent to the electrical conductor.

12. The PCBA of claim 11, wherein the point field detector is a Hall-effect sensor.

13. The PCBA of claim 12, wherein the Hall-effect sensor is centered between the first and second flux shield portions.

14. The PCBA of claim 13, wherein the first and second flux shield portions are separated from each other by a distance of about 12 mm.

15. The PCBA of claim 11, wherein the first and second flux shield portions include a respective planar base portion intersected by first and second radial wall members.

16. The PCBA of claim 15, wherein the second radial wall member extends through the substrate and protrudes from the second primary surface to within about 1-2 mm of the conductor.

17. The PCBA of claim 16, wherein each of the respective planar base portions defines a hole, the electrical device further comprising: a pair of fasteners connecting the first and second flux shield portions to the substrate through the hole of the respective base portions.

18. The PCBA of claim 11, wherein the relative magnetic permeability is in a range of about 100 to about 1000.

19. The PCBA of claim 11, wherein the PCBA is an integrated current sense board and gate drive board.
